(19) United States
(12) Patent Application Publication
(10) Pub. No.: US 2007/0190729 A1
(43) Pub. Date: Aug. 16, 2007

(54) Apparatus and method for reflowing photoresist

(76) Inventor: Jong-Woo Yoon, Seoul (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/703,690

(22) Filed: Feb. 8, 2007

(30) Foreign Application Priority Data
Feb. 15, 2006 (KR) 2006-0014853

(51) Int. Cl. H01L 21/8234

(52) U.S. Cl. 438/275

(57) ABSTRACT

A method of and an apparatus for reflowing photoresist ensure that the photoresist is heated uniformly when it reaches a desired temperature at which the photoresist is to reflow. The photoresist reflowing apparatus includes a chamber, a plate disposed within the chamber and on which a substrate having a photoresist pattern thereon is to be supported, a motor coupled with the plate to rotate the plate, and a microwave source which emits a beam of microwaves with directionality. The microwave source is oriented to irradiate the substrate such that the beam of microwaves is located between the center of the substrate and the outer peripheral edge of the substrate. The temperatures of the photoresist pattern may be detected at local regions on the substrate. In this case, the speed of rotation of the substrate is adjusted if at least one of the temperatures of the photoresist pattern at a local region of the substrate is not within the allowable range.

### BACKGROUND OF INVENTION

1. Field of the Invention

The present invention relates to a method of and an apparatus for reflowing photoresist. More particularly, the present invention relates to a method of and an apparatus for reflowing photoresist using microwaves.

2. Description of the Related Art

One of the important aspects of the manufacturing of semiconductor devices is the forming of a desired circuit pattern on a semiconductor substrate, such as a wafer. Photolithography is a process commonly used to form circuit patterns on semiconductor substrates. Photolithography begins with a process of coating a substrate with a photoresist, which is a material having a chemical property that changes when the material is irradiated. Then, the coated substrate is aligned with a reticle having a pattern corresponding to the circuit pattern to be formed. Subsequently, the substrate is exposed to light of a predetermined wavelength transmitted through the reticle. As a result, an image of the pattern of the reticle is transferred to the layer of photoresist on the substrate. Next, a developing solution is supplied onto the exposed substrate to remove select portions of the exposed layer of photoresist and thereby pattern the photoresist. Also, the substrate is baked before or after the exposure or developing process to treat the layer of photoresist. In any case, photolithography forms a photoresist pattern, similar to the pattern of the reticle, on the substrate. Then, a desired circuit pattern is formed on the substrate by etching the substrate using the photoresist pattern as a mask.

Meanwhile, current information processing and communications technologies demand semiconductor devices which are more and more compact. Accordingly, techniques in the manufacturing of semiconductor devices are being developed and improved with an aim towards increasing the degree of integration of the devices. To this end, efforts have been concentrated on minimizing the critical dimensions (CD), e.g., the line widths, of the circuit patterns formed on the substrate. However, limitations imposed by the optics of exposure apparatus of conventional photolithographic equipment make it difficult to form patterns having very fine line widths.

Therefore, a process of heating the photoresist pattern at a high temperature of about 200° C. after the developing process to cause the photoresist to reflow has been recently proposed as a technique by which a circuit pattern having a very fine line width can be formed. In this case, the fineness of the line width of the circuit pattern is proportional to the extent to which the photoresist is caused to reflow. This method is carried out using a baking apparatus having a chamber and a hot plate disposed within the chamber.

However, the temperature of the hot plate of the conventional baking apparatus varies amongst the central region of the hot plate, and front, rear, right and left edges of the hot plate. Therefore, the amount by which the photoresist pattern reflows varies across the substrate in accordance with the differences in temperature amongst the local regions of the hot plate when the photoresist pattern is heated using a conventional baking apparatus. Thus, a circuit pattern having a uniform and desired critical dimension (CD) can not be formed.

### SUMMARY OF THE INVENTION

Therefore, an object of the present invention is to provide a method and apparatus by which fine circuit patterns having uniform critical dimensions can be produced.

A more specific object of the present invention is to provide a method of and an apparatus for heating photoresist uniformly across the surface of a substrate.

Still, another object of the present invention is to provide a method of and an apparatus for reflowing a photoresist pattern uniformly across the surface of a substrate.

According to one aspect of the present invention, a photoresist reflowing apparatus includes a chamber, a plate disposed within the chamber and on which a substrate having a photoresist pattern formed is to be placed, a motor coupled with the plate to rotate the plate, and a microwave source which irradiates the substrate with a beam of microwaves. The microwave source is oriented so that the beam of microwaves is directed onto the substrate between a center of the substrate and an outer peripheral edge of the substrate.

The microwave source may be integrated with the chamber. In this case, the microwave source preferably includes a microwave generator, an antenna extending into the chamber from the microwave generator for transmitting microwaves generated by the microwave generator, and a wave guide extending around the antenna for guiding the microwaves as a beam towards the substrate. Also, preferably, the microwave source is disposed at the top of the chamber above the plate.

The photoresist reflowing apparatus may further include a plurality of temperature sensors within the chamber to detect the temperatures of the photoresist pattern at several local regions of the substrate, respectively. In this case, the temperature sensors may include a central temperature sensor which detects the temperature of the photoresist pattern at a central region of the substrate, and edge temperature sensors which detect temperatures of the photoresist pattern along the outer peripheral edge of the substrate. The central temperature sensor and the edge temperature sensors may be disposed above the substrate and in the same plane. Four edge temperature sensors may be spaced from one another by equal angular intervals so as to be respectively disposed to the front, rear, left and right of the central temperature sensor.

The photoresist reflowing apparatus may further include a controller operatively electronically connected to the temperature sensors and the motor to control the rotational speed of the motor according to the temperatures detected by the temperature sensors.

According to another aspect of the present invention, a method of processing a substrate having photoresist thereon includes rotating the substrate, and irradiating the rotating substrate with a beam of microwaves whose center is directed onto the substrate between the center of the substrate and the outer peripheral edge of the substrate. The substrate may be rotated continuously as it is irradiated with the microwaves.

Also, during this time, the temperatures of the photoresist can be detected at several local regions of the substrate, respectively. In this case, it is determined as to whether the temperatures fall within an allowable range. If not, then the speed of rotation of the substrate is adjusted to reduce the temperature differences between the local regions of the substrate.

In accordance with yet another aspect of the present invention, a method of processing a substrate having photoresist thereon includes irradiating the substrate with microwaves, detecting the temperatures of the photoresist at local regions of the substrate, respectively, and determining whether the temperatures fall within an allowable range.

In accordance with another aspect of a substrate processing method of the present invention, the temperatures of the local regions of the substrate are monitored to determine whether the substrate has reached a predetermined temperature at which the photoresist will reflow at all of the local regions. The irradiation of the substrate with the microwaves is stopped when it has been determined that all of the local regions of the substrate are within the allowable range and the temperatures of all of the local regions of the substrate have reached the predetermined temperature at which the photoresist will reflow.

### BRIEF DESCRIPTION OF THE DRAWINGS

The above and other objects, features and advantages of the present invention will become more apparent to those of ordinary skill in the art from the following detailed description of the preferred embodiments thereof made with reference to the attached drawings in which:

FIG. 1 is a sectional view of a photoresist reflowing apparatus according to the present invention;

FIG. 2 is a plan view of the substrate supported in the apparatus of FIG. 1 and illustrating the location of temperature sensors of the apparatus disposed above the substrate;

FIG. 3 is a flow chart of a photoresist reflowing method according to the present invention; and

FIGS. 4A to 4D are each a sectional view of part of a substrate and together illustrate a method of forming contact holes according to the present invention.

### DETAILED DESCRIPTION OF THE PREFERRED EMBODIMENTS

The present invention will now be described more fully hereinafter with reference to the accompanying drawings. Note, like numbers designate like elements throughout the drawings.

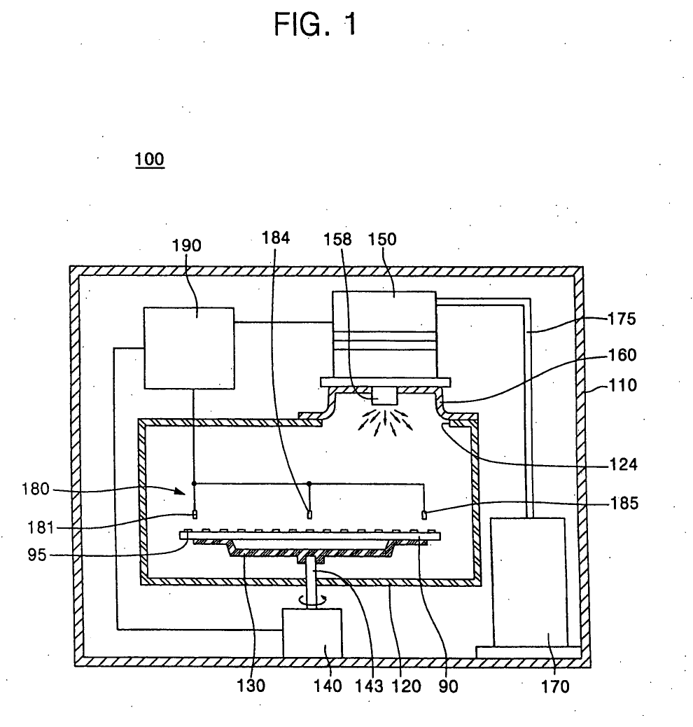

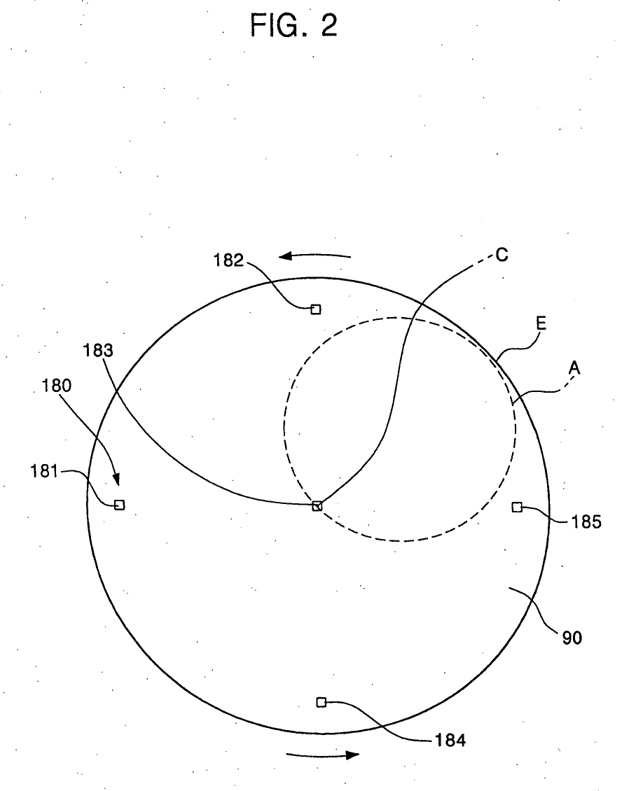

Referring to FIGS. 1 and 2, a photoresist reflowing apparatus 100 according to the present invention includes a casing 110 and a chamber 120 disposed within the casing 110. The chamber 120 provides a space within which photoresist reflowing processes are carried out, and the casing 110 serves to enclose the chamber 120. The chamber 120 may be made of material, for example, a metallic material, which can reflect microwaves. Also, the casing 110 and the chamber 120 are spaced apart such that various other parts of the photoresist reflowing apparatus 100, as will be described later on, can be installed in the space between the casing 110 and the chamber 120. In addition, each of the casing 110 and the chamber 120 has a respective gate (not shown) on one side of the apparatus 100. Thus, a substrate 90, such as a wafer, can be loaded into the chamber 120 through the gates.

A plate 130 is disposed within the chamber 120 to support the substrate 90. The plate 130 may be made of material which transmits microwaves, i.e., which is substantially transparent to microwaves. For example, the plate 130 may be made of glass or ceramics. Also, a motor 140 for rotating the plate 130 is provided outside the chamber 120. More specifically, the motor 140 is disposed below the plate 130 between the chamber 120 and the casing 110. The motor 140 is coupled to a bottom central portion of the plate 130 via a rotary shaft 143 which extends into the chamber 120.

A microwave generator 150 for irradiating the substrate 90 with microwaves is disposed at the top of the chamber 120. The microwave generator 150 may be a magnetron. Specifically, the microwave generator 150 directs a beam of microwaves onto the substrate 90 such that the center of the beam (“C” in FIG. 2) is located between the axis of rotation of the rotary shaft and the outer peripheral edge of the plate 130. 143 Hence, the center C of the beam will be located between the center of the substrate 90 and the outer peripheral edge of the substrate 90. Reference character “A” in FIG. 2 denotes the area at which the beam is projected onto the substrate 90, this area containing an intensive amount of microwaves.

The microwave generator 150 may be integrated with the top of the chamber 120 as facing the center C of the area A. In this case, the top of the chamber 120 has an opening 124 therethrough. A wave guide 160 which guides microwaves covers the opening 124, and the microwave generator 150 is disposed on the wave guide 160. Reference numeral 158 denotes an antenna from which microwaves generated in the microwave generator 150 are emitted into the chamber 120. Reference numeral 170 denotes a high voltage generator, and reference numeral 175 denotes a power supply line by which a high voltage produced by the high voltage generator 170 is transmitted to the microwave generator 150.

The photoresist reflowing apparatus 100 may further include a plurality of temperature sensors 180 disposed within the chamber 120, and a controller 190 which controls the rotational speed of the motor 140 according to the temperatures detected by the temperature sensors 180. The temperature sensors 180 detect, in real-time, temperatures of local regions of a photoresist pattern 95 on the substrate 90. To this end, the temperature sensors 180 may each be a non-contact type of infrared sensor. Specifically, the temperature sensors 180 include a central temperature sensor 183 which is axially aligned with the rotary shaft 143 so as to detect the temperature of the photoresist 95 at a central portion of the substrate 90, and a plurality of edge temperature sensors 181, 182, 184 and 185 which are disposed alongside the outer peripheral portion of the plate 130 so as to detect temperatures of the photoresist 95 along the outer peripheral edge of the substrate 90.

More specifically, the central temperature sensor 183 and the edge temperature sensors 181, 182, 184 and 185 may be disposed above the plate 130 (as shown) or may be disposed along the inner wall of the chamber 120 because the sensors are each a non-contact type of sensor. If the central temperature sensor 183 and the edge temperature sensors 181, 182, 184 and 185 are disposed above the plate 130, the edge temperature sensors 181, 182, 184 and 185 may be disposed in the same plane as the central temperature sensor 183. Also, the edge temperature sensors 181, 182, 184 and 185 may be disposed at equal angular intervals about the central temperature sensor 183.

The controller 190 is connected to the temperature sensors 180 and the motor 140, respectively. The controller 190 determines whether the temperatures of the photoresist 95 detected by the temperature sensors 180 at individual spots on the substrate 90 fall within a predetermined allowable range; the controller 190 then controls the motor 140 to rotate the substrate 90 according to this determination. The allowable range is based on various factors, such as the type of photoresist formed on the substrate 90, and the degree to which the photoresist is to reflow on the substrate 90. For instance, the allowable range may be T±5° C., wherein T is the desired temperature to which the photoresist is to be heated. Therefore, according to the present invention, the photoresist pattern 95 on the substrate 90 can be uniformly heated. Thus, the photoresist pattern 95 will reflow uniformly.

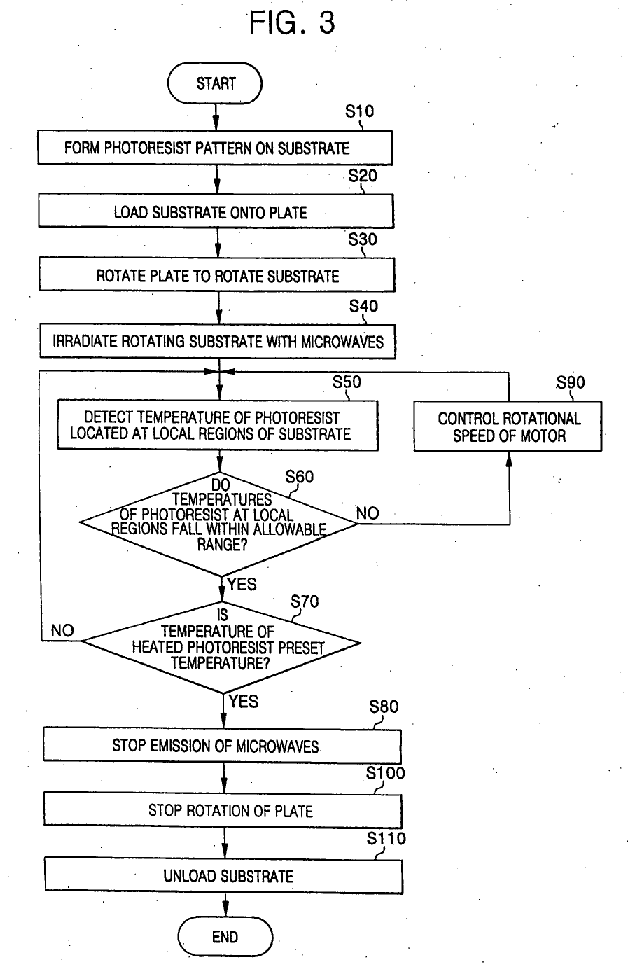

A method of reflowing the photoresist using the photoresist reflowing apparatus 100 will now be described with reference to FIGS. 1-3.

First, a substrate is prepared. Specifically, the substrate 90 is coated with photoresist, exposed, developed, and baked, etc. to form a photoresist pattern 95 on the substrate 90 (S10).

Subsequently, the substrate 90 is loaded into the chamber 120, and placed on the plate 130 within the chamber 120 (S20).

Next, the plate 130 is rotated by the motor 140 (S30). Accordingly, the substrate 90 is also rotated. At this time, the substrate 90 may be rotated at a low speed of several tens of revolutions per minute (RPM).

Then, the microwave generator 150 irradiates the rotating substrate 90 with microwaves so that the photoresist pattern 95 on the substrate 90 begins to reflow. At this time, the center C of the area over which the substrate 90 is irradiated extends between the center of the substrate 90 and the outer peripheral edge of the substrate 90. Therefore, the entire surface of the substrate 90 will be heated uniformly by the microwaves so as to minimize temperature differences in the photoresist pattern 95 between the center and outer peripheral edge of the substrate 90. As a result, the photoresist pattern 95 on the substrate 90 will reflow uniformly.

Also, at this time, the temperature sensors 180 detect the temperatures of the photoresist pattern 95 at various locations on the substrate 90 (S50), and transmit the detected temperature values to the controller 190. Then, the controller 190 determines whether the detected temperature values of the photoresist 95 fall within an allowable range (S60). If the temperatures of the photoresist pattern 95 at some of the local regions on the substrate 90 are not within the allowable range, the controller 190 controls the motor 140 to rotate the substrate 90 in such a way as to minimize the temperature differences (S90). For instance, the controller 190 may control the motor 140 to rotate the substrate 90 such that any portion of the photoresist pattern 95 having a temperature below the allowable range passes through the area A more slowly than the other portions of the photoresist pattern 95. Thus, the flux of the microwaves is varied across the surface of the substrate 90 so that the portion/portions having the lower temperature is/are heated to a greater extent. However, if the temperatures of the photoresist pattern 95 at all of the local regions of the substrate 90 fall within the allowable range, the controller 190 controls the motor 140 to maintain the rotational speed of the substrate 90.

The temperature sensors 180 continue to monitor the temperatures of the photoresist pattern 95 at the local regions. If all of the temperatures of the photoresist pattern 95 fall within the allowable range, the controller 190 determines whether temperature of the photoresist pattern 95 has reached a predetermined desired temperature (S70). In this case, if the controller 190 determines that the temperature of the heated photoresist 95 is below the predetermined temperature, the controller 190 controls the motor 140 to keep rotating the substrate 90, controls the microwave generator 150 to continue emitting microwaves, and continues monitoring the temperatures of the photoresist pattern 95 via the temperature sensors 180. However, if the controller 190 determines that the temperature of the heated photoresist pattern 95 has reached the predetermined desired temperature, the controller 190 controls the microwave generator 150 to stop emitting microwaves (S80), controls the motor 140 to stop the plate 130 (S100), and controls a transfer device (not shown) to unload the substrate 90 from the chamber 120 (S110). Thus, the photoresist pattern 95 is caused to reflow across the entire substrate 90 at the desired predetermined temperature.

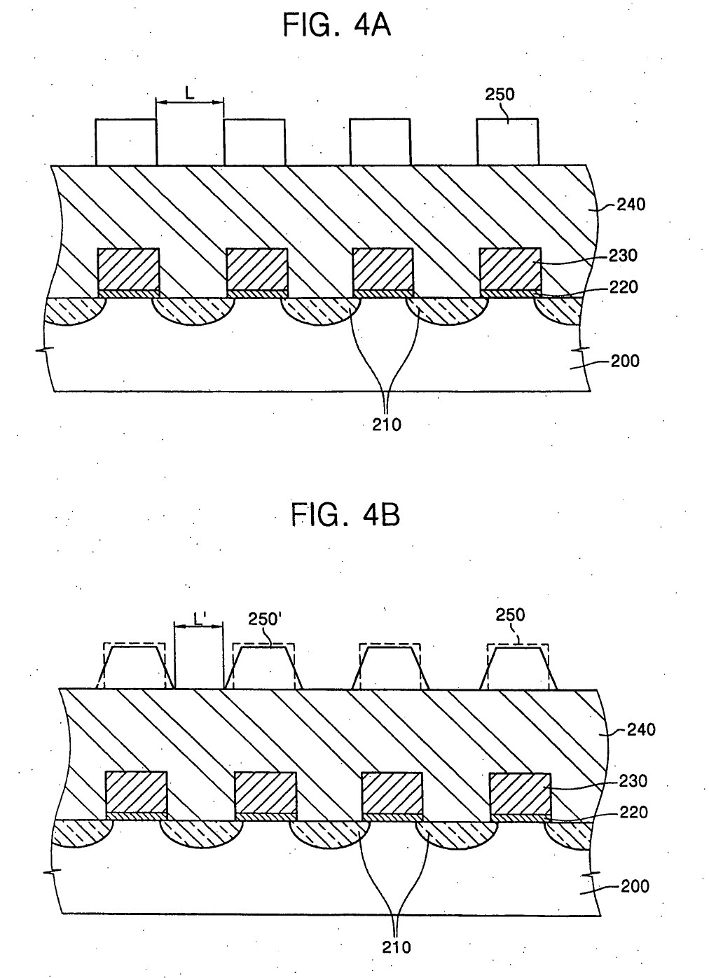

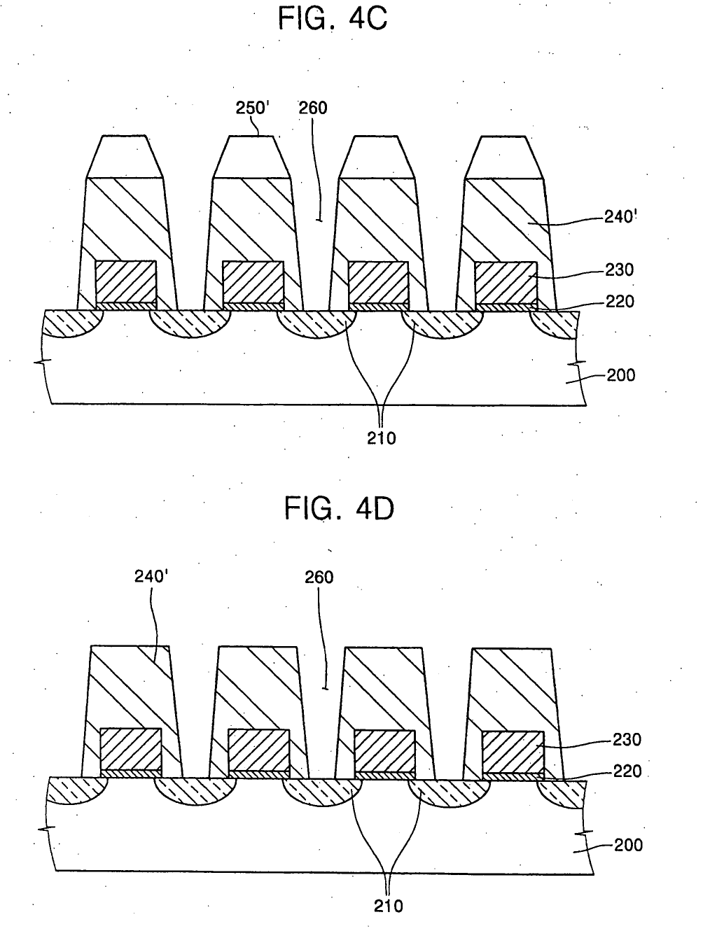

A method of forming contact holes in a substrate as an application of the present invention will now be described in detail with reference to FIGS. 4A to 4D.

First, an interlayer insulating layer 240 is formed on a substrate 200 having source/drain areas 210, a gate oxide film 220, and gate electrodes 230 formed thereon. Next, the substrate 200 is coated with photoresist to form a layer of the photoresist on the interlayer insulating layer 240. The layer of photoresist is exposed, developed, and baked, thereby forming a photoresist pattern 250 having a predetermined spacing (“L′” of FIG. 4A) between features of the pattern 250.

Thereafter, the photoresist pattern 250 is heated by irradiating the substrate 200 with microwaves while the substrate 200 is rotated. As a result, the photoresist pattern 250 reflows as shown in FIG. 4B. Thus, a photoresist pattern 250‘having a spacing L’ which is narrower than the original spacing L is formed.

Next, the interlayer insulating layer 240 is etched using the photoresist pattern 250′ as a mask. Thus, contract holes 260 having a diameter equal to the spacing (L′) between the features of the photoresist pattern 250 are formed (FIG. 4C). Finally, the photoresist pattern 250′ is removed (FIG. 4D). Note, reference numeral 240′ in FIGS. 4C and 4D denotes the interlayer insulating layer with the contract holes 260 formed therein.

According to the present invention as described above, microwaves are emitted onto the substrate to cause photoresist on the substrate to reflow. Thus, the photoresist and, in particular, a photoresist pattern, can reflow uniformly.

Moreover, according to the method and apparatus of the present invention, it is determined as to whether the temperatures of photoresist at any of several local regions of the substrate fall within an allowable range. If not, the temperature of the photoresist is adjusted at that region or regions of the substrate where the temperature is outside the allowable range. In particular, the flux of the microwaves is changed at a region of the substrate where the temperature is outside the allowable range. This can be done by appropriately controlling the speed of rotation of the substrate.

Finally, although the present invention has been described in connection with the preferred embodiments thereof, it is to be understood that the scope of the present invention is not so limited. On the contrary, various modifications of and changes to the preferred embodiments will be apparent to those of ordinary skill in the art. Thus, changes to and modifications of the preferred embodiments may fall within the true spirit and scope of the invention as defined by the appended claims.

What is claimed is:

1. A photoresist reflowing apparatus comprising:
a chamber;
a plate disposed within the chamber and sized to support a substrate;
a motor coupled to the plate to rotate the plate about an axis of rotation; and
a microwave source that emits a beam of microwaves within the chamber and is oriented so that the beam of microwaves is directed onto the substrate between a center of the substrate and an outer peripheral edge of the substrate.

2. The photoresist reflowing apparatus according to claim 1, wherein the microwave source is disposed at the top of the chamber.

3. The photoresist reflowing apparatus according to claim 2, wherein the microwave source includes a microwave generator, an antenna extending within the chamber from the microwave generator and from which microwaves generated by the microwave generator are transmitted, and a wave guide extending around the antenna.

4. The photoresist reflowing apparatus according to claim 1, further comprising a plurality of temperature sensors which are provided within the chamber and are spaced from one another about the plate to detect temperatures at local regions on a substrate supported on the plate.

5. The photoresist reflowing apparatus according to claim 2, further comprising a controller which is operatively connected to the temperature sensors to receive signals from the temperatures sensors indicative of the temperatures sensed by the temperature sensors, and is operatively connected to the motor to control the rotational speed of the motor according to the temperatures sensed by the temperature sensors.

6. The photoresist reflowing apparatus according to claim 4, wherein the temperature sensors includes a central temperature sensor disposed adjacent the axis of rotation of the plate, and edge temperature sensors spaced about the outer periphery of the plate.

7. The photoresist reflowing apparatus according to claim 6, wherein the central temperature sensor and the edge temperature sensors are disposed above the plate, and the edge temperature sensors comprise four sensors spaced at equal angular intervals from one another with respect to the central temperature sensor.

8. A substrate processing method comprising:
rotating a substrate having photoresist thereon; and
irradiating the substrate with a beam of microwaves which is directed onto the substrate between a center of the substrate and an outer peripheral edge of the substrate.

9. The method according to claim 8, further comprising detecting the temperatures of the photoresist at local regions of the substrate, respectively, determining whether the temperatures fall within an allowable range, and adjusting the speed of rotation of the substrate if at least one of the temperatures of the photoresist at a local region of the substrate is not within the allowable range.

10. The method according to claim 9, wherein the adjusting of the speed of rotation of the substrate comprises controlling the speed of rotation of the substrate so that a portion of the photoresist having a temperature below the allowable range passes through the beam of microwaves more slowly than a portion of the photoresist having a temperature within the allowable range.

11. The method according to claim 8, wherein the substrate is irradiated with the microwaves while the substrate is continuously rotated.

12. The method according to claim 8, wherein the irradiating of the substrate with the beam of microwaves is carried out until the substrate reaches a temperature at which the photoresist will reflow.

13. The method according to claim 9, further comprising determining whether the substrate has reached a temperature at which the photoresist will reflow once all of the temperatures of the photoresist at the local regions of the substrate are within the allowable range, and stopping the irradiation of the substrate with the microwaves when it has been determined that all of the temperatures of the photoresist at the local regions of the substrate are within the allowable range.

14. A substrate processing method comprising:
irradiating a substrate, having photoresist thereon, with microwaves;
detecting the temperatures of the photoresist at local regions of the substrate, respectively; and
determining whether the temperatures fall within an allowable range.

15. The method of claim 14, further comprising varying the flux of the microwaves across the substrate if at least one of the temperatures of the photoresist at a local region of the substrate is not within the allowable range.

16. The method according to claim 14, wherein the irradiating of the substrate with the beam of microwaves is carried out until the substrate reaches a temperature at which the photoresist will reflow.

17. The method according to claim 14, further comprising determining whether the substrate has reached a desired temperature, at which the photoresist will reflow, once all of the temperatures of the photoresist at the local regions of the substrate are within the allowable range, and stopping the irradiation of the substrate with the microwaves when it has been determined that all of the temperatures of the photoresist at the local regions of the substrate have reached the desired temperature.
